(19) United States
(12) Patent Application Publication
(10) Pub. No.: US 2025/0048888 A1
(43) Pub. Date: Feb. 6, 2025

(54) LIGHT EMITTING ELEMENT, COMPOUND FOR THE SAME, AND DISPLAY DEVICE INCLUDING THE LIGHT EMITTING ELEMENT

(71) Applicant: Samsung Display Co., LTD., Yongin-si (KR)

(72) Inventors: WONBEOM LEE, Yongin-si (KR); WONJIN KIM, Yongin-si (KR); HYUK-HWAN KIM, Yongin-si (KR); JUNWOO YOU, Yongin-si (KR); JEONGSEOK LEE, Yongin-si (KR); SUK WON JUNG, Yongin-si (KR)

(21) Appl. No.: 18/636,438

(22) Filed: Apr. 16, 2024

(30) Foreign Application Priority Data
Aug. 2, 2023 (KR) 10-2023-0100980

(51) Int. Cl. H10K 59/80; H10K 59/12

(52) U.S. Cl. CPC H10K 59/873; H10K 59/1201; H10K 59/8794

(57) ABSTRACT

An electronic apparatus includes a display panel in which a central region and an edge region, adjacent to the central region, are defined, a functional layer disposed on a rear surface of the display panel and overlapping the central region, and a dam disposed on the rear surface of the display panel and overlapping the edge region. The functional layer includes a shock-absorbing material and a light-shielding material, and the dam includes a light-shielding material. A side surface of the functional layer is in contact with the dam.

This application claims priority to Korean Patent Application No. 10-2023-0100980, filed on Aug. 2, 2023, and all the benefits accruing therefrom under 35 U.S.C. § 119, the content of which in its entirety is herein incorporated by reference.

### BACKGROUND

### 1. Field

The disclosure herein relates to an electronic apparatus including, on a rear surface of a display panel, a functional layer and a dam which have a light-shielding property, and a method of manufacturing the electronic apparatus.

### 2. Description of the Related Art

Multimedia electronic apparatuses such as televisions, mobile phones, tablet computers, navigation systems, and game consoles may include display devices to display an image and electronic components which perform various functions. As electronic apparatuses have higher performance and smaller thickness, electronic components installed in the electronic apparatuses have a larger capacity and become more highly integrated. Accordingly, the electronic components generate substantial heat inside the electronic apparatuses. The heat generated inside the electronic apparatuses reduces a service life of a product or causes the electronic components and display devices to break down or malfunction.

### SUMMARY

The disclosure provides an electronic apparatus with improved reliability and a method of manufacturing the electronic apparatus.

An embodiment of the invention provides an electronic apparatus including a display panel in which a central region and an edge region, adjacent to the central region, are defined, including a functional layer disposed on a rear surface of the display panel and overlapping the central region, and including a dam disposed on the rear surface of the display panel and overlapping the edge region. The functional layer includes a shock-absorbing material and a light-shielding material, the dam includes the light-shielding material, and a side surface of the functional layer is in contact with the dam.

In an embodiment, a thickness of the functional layer may be uniform along the rear surface of the display panel.

In an embodiment, the thickness of the functional layer may be equal to or less than a height of the dam.

In an embodiment, the dam may include a plurality of sub-dams sequentially stacked one on another, and the plurality of sub-dams may have a same material as each other.

In an embodiment, the functional layer may include a first functional layer disposed on the rear surface of the display panel and a second functional layer disposed on the first functional layer.

In an embodiment, the first functional layer and the second functional layer may include a same material as each other.

In an embodiment, the edge region may include a first edge region surrounding the central region and a second edge region surrounded by the central region, and the dam may include a first dam overlapping the first edge region and a second dam overlapping the second edge region.

In an embodiment, the side surface of the functional layer may include a first side surface in contact with the first dam and a second side surface in contact with the second dam.

In an embodiment, the functional layer may be provided with a functional hole overlapping the second edge region, where the function hole may be defined by the second side surface.

In an embodiment, the functional hole may be provided in plurality, and the display panel may be provided with a panel hole defined therein to overlap at least one selected from the plurality of functional holes.

In an embodiment, a size of the panel hole may be less than a size of the functional hole overlapping the panel hole.

In an embodiment, the electronic apparatus may further include an electro-optical module overlapping the functional hole.

In an embodiment, the electronic apparatus may further include a heat dissipation layer spaced apart from the rear surface of the display panel and disposed under the functional layer and the dam.

In an embodiment, the heat dissipation layer my include a heat-dissipating material and an electromagnetic shielding material.

In an embodiment of the invention, a method for manufacturing an electronic apparatus includes providing a display panel in which a central region and an edge region, adjacent to the central region, are defined, forming a dam, on a rear surface of the display panel, to overlap the edge region, and forming a functional layer, on the rear surface of the display panel, to overlap the central region, wherein the dam is in contact with a side surface of the functional layer.

In an embodiment, the dam may include a plurality of sub-dams which are sequentially stacked one on another, and the forming the dam may include forming a first sub-dam among the plurality of sub-dams on the rear surface of the display panel, and forming a second sub-dam among the plurality of sub-dams on the first sub-dam.

In an embodiment, the providing the functional layer may include applying a first preliminary functional layer to overlap the central region on the rear surface of the display panel, providing a first functional layer by performing first curing on the first preliminary functional layer, applying a second preliminary functional layer on the first functional layer, and providing a second functional layer by performing second curing on the second preliminary functional layer.

In an embodiment, the edge region may include a first edge region surrounding the central region and a second edge region surrounded by the central region. The forming of the dam may include forming a first dam to overlap the first edge region, and forming a second dam to overlap the second edge region.

In an embodiment, the display panel may be provided with a panel hole defined therein to overlap an electronic module, and the second dam may surround the panel hole.

In an embodiment, the method for manufacturing an electronic apparatus may include forming an adhesive layer on the functional layer and the dam, and forming a heat dissipation layer on the adhesive layer.

### BRIEF DESCRIPTION OF THE DRAWINGS

The above and other features of the invention will become more apparent by describing in further detail embodiments thereof with reference to the accompanying drawings, in which:

FIG. 1 is a perspective view of an electronic apparatus according to an embodiment of the invention;

FIG. 2 is an exploded perspective view of an electronic apparatus according to an embodiment of the invention;

FIG. 3 is a block diagram of an electronic apparatus according to an embodiment of the invention;

FIG. 4A is a plan view of a display panel according to an embodiment of the invention;

FIG. 4B is a cross-sectional view of a display panel and a functional layer according to an embodiment of the invention;

FIG. 5 is a plan view of an electronic apparatus according to an embodiment of the invention;

FIG. 6A is a cross-sectional view of a portion of an electronic apparatus taken along line I-I′ of FIG. 5;

FIG. 6B is a cross-sectional view of a portion of an electronic apparatus taken along line II-II′ of FIG. 5;

FIG. 7A is a plan view of an electronic apparatus according to an embodiment of the invention;

FIG. 7B is a cross-sectional view of a portion of an electronic apparatus taken along line III-III′ of FIG. 7A;

FIG. 8 is a flowchart of a method for manufacturing a display device according to an embodiment of the invention;

FIGS. 9A to 9E are cross-sectional views of some operations of a method for manufacturing an electronic apparatus according to an embodiment of the invention; and

FIGS. 10A to 10C are cross-sectional views of some operations of a method for manufacturing an electronic apparatus according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, it will be understood that when an element (or a region, a layer, a portion, or the like) is referred to as being “on”, “connected to” or “coupled to” another element, it may be directly disposed on, connected or coupled to the other element, or intervening elements may be disposed therebetween.

Like numbers or symbols refer to like elements throughout. Also, in the drawings, the thicknesses, ratios, and dimensions of the elements are exaggerated for effective description of the technical contents.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Although the terms first, second, etc. may be used to describe various elements, these elements should not be limited by these terms. These terms are only used to distinguish one element from another element. For example, a first element may be referred to as a second element, and similarly, a second element may also be referred to as a first element without departing from the scope of the disclosure. The singular forms include the plural forms as well, unless the context clearly indicates otherwise.

Also, terms of “below”, “on lower side”, “above”, “on upper side”, or the like may be used to describe the relationships of the elements illustrated in the drawings. These terms have relative concepts and are described on the basis of the directions indicated in the drawings.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skills in the art to which this disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described with reference to the drawings.

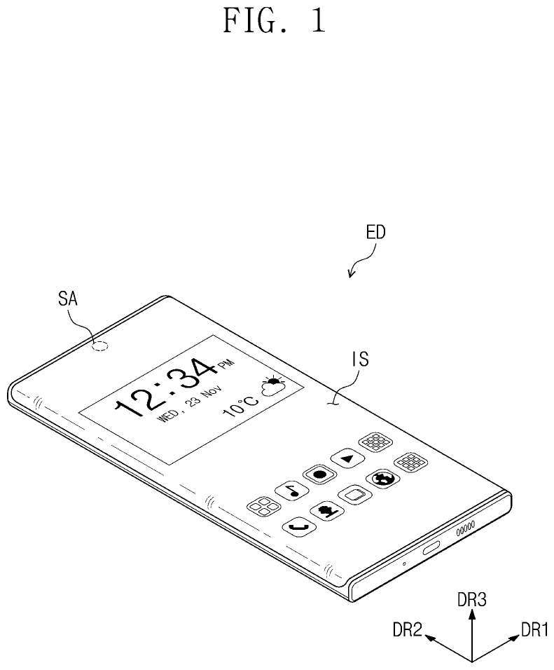

FIG. 1 is a perspective view of an electronic apparatus according to an embodiment of the invention.

Referring to FIG. 1, an embodiment of an electronic apparatus ED may be activated in response to an electrical signal and may display an image. In an embodiment, for example, the electronic apparatus ED may be a small- and medium-sized electronic apparatus such as a monitor, a mobile phone, a tablet personal computer (PC), a car navigation system, or a game console, as well as a large-sized apparatus such as a television or an external billboard. However, embodiments of the electronic apparatus ED are examples and not limited to any one embodiment without departing from the spirit of the invention. In an embodiment, as shown in FIG. 1, the electronic apparatus ED may be a mobile phone, but not being limited thereto.

In an embodiment, the electronic apparatus ED may have, on a plane, a rectangular shape having short sides extending in a first direction DR1 and long sides extending in a second direction DR2 which crosses the first direction DR1. However, an embodiment of the invention is not limited thereto, and the electronic apparatus ED may have various shapes such as a circular shape, a polygonal shape, or the like on the plane.

In an embodiment, a third direction DR3 may be defined as a perpendicular direction to a plane defined by the first direction DR1 and the second direction DR2. A front surface (or a top surface) and a rear surface (or a bottom surface) of each member constituting the electronic apparatus ED may be opposed to each other in the third direction DR3, and the normal direction of each of the front surface and the rear surface may be substantially parallel to the third direction DR3. A distance between the front surface and the rear surface defined along the third direction DR3 may correspond to a thickness of a member.

In this specification, “on a plane” may be defined as “seen in the third direction DR3.” In this specification, “on a cross section” may defined as “seen in the first direction DR1 or in the second direction DR2.” It would be understood that the directions indicated by the first to third direction DR1, DR2, and DR3 may have a relative concept and may thus be changed to other directions.

In an embodiment, the electronic apparatus ED may be rigid or flexible. The word “flexible” may mean “being bendable” and may include all structures, for example, a structure bendable to a level of several nanometers as well as a fully folded structure. In an embodiment, for example, a flexible electronic apparatus ED may include a curved device or a foldable device.

The electronic apparatus ED may display an image through a display surface IS. The display surface IS may correspond to the front surface of the electronic apparatus ED. In an embodiment, the display surface IS may include a flat surface defined by the first direction DR1 and the second direction DR2, and may display an image in the third direction DR3 perpendicular thereto. The display surface IS may further include curved surfaces bent from at least two sides of the flat surface respectively. However, a shape of the display surface IS may not be limited thereto. In an embodiment, for example, the display surface IS may include only a flat surface, or may further include at least two curved surfaces, for example, four curved surfaces respectively bent from four sides of the flat surface.

A partial region of the display surface IS may be defined as a sensing region SA. FIG. 1 illustrates an embodiment where a single sensing region SA is defined as an example, but the number of sensing regions SA is not limited thereto. The sensing region SA may be a region having a higher light transmittance compared to other regions in the display surface IS. The sensing region SA may transmit a light signal while displaying an image.

The electronic apparatus ED according to an embodiment may sense an external input applied from the outside. The external input may include various forms of input. In an embodiment, for example, the external input may include physical force, pressure, heat, light, etc. The external input may include an input (for example, hovering) applied close to the electronic apparatus ED as well as an input (for example, a contact by a user's hand or a pen) of contact with the electronic apparatus ED.

The electronic apparatus ED may sense a user's input through the display surface IS defined on a front surface and respond to a sensed input signal. However, a region of the electronic apparatus ED which senses the external input may not be limited to the front surface of the electronic apparatus ED, and may be changed depending on a design of the electronic apparatus ED. In an embodiment, for example, the electronic apparatus ED may sense the user's input applied to a side surface or a rear surface of the electronic apparatus ED.

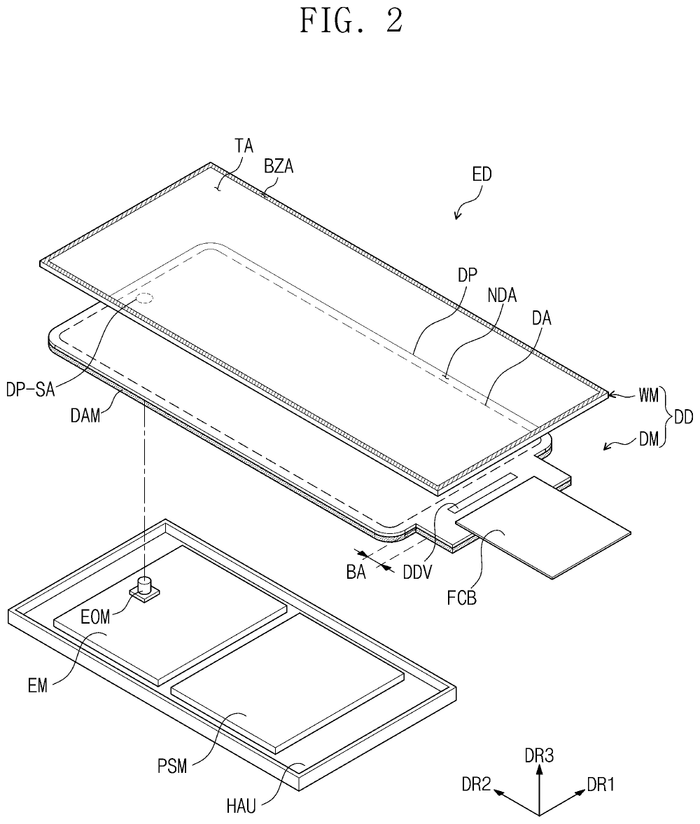

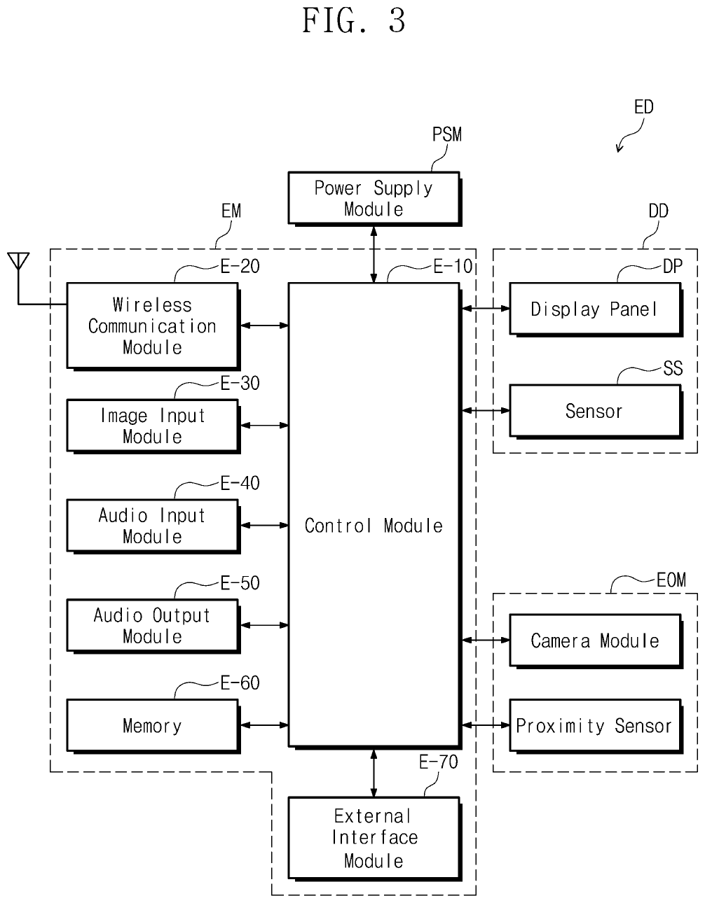

FIG. 2 is an exploded perspective view of an electronic apparatus according to an embodiment of the invention. FIG. 3 is a block diagram of an electronic apparatus according to an embodiment of the invention.

Referring to FIGS. 2 and 3, an embodiment of the electronic apparatus ED may include a display device DD, an electronic module EM, an electro-optical module EOM, a power supply module PSM, and a housing HAU.

The display device DD may generate an image and sense an external input. The display device DD may include the window WM and the display module DM. The display module DM may include a display panel DP, and may further include at least one component disposed on the display panel DP. FIG. 2 schematically illustrates only the display panel DP among the stacked structures of the display module DM, but an embodiment of the display module DM is not limited thereto.

The window WM may be disposed on the display module DM. The window WM may cover the front surface of the display module DM and protect the display module DM from an external impact and scratches. The window WM may be coupled to the display module DM through an adhesive layer.

The window WM may include an optically transparent insulating material. In an embodiment, for example, the window WM may include, as a base film, a glass film or a synthetic resin film. The window WM may have a single-layered or multi-layered structure. In an embodiment, for example, the window WM may include a plurality of synthetic resin films bonded with an adhesive, or a glass film and a synthetic resin film bonded with an adhesive. The window WM may further include a functional layer, such as an anti-fingerprint layer, a phase control layer, and a hard coating layer, disposed on the base film.

The front surface of the window WM may correspond to the front surface of the electronic apparatus ED. The front surface of the window WM may include a transmission region TA and a bezel region BZA.

The transmission region TA may be optically transparent. The transmission region TA may transmit an image provided by the display panel DP, and a user may view the image through the transmission region TA. In an embodiment, as shown in FIG. 2, the transmission region TA may have a quadrilateral shape, but the transmission region TA may have various shapes, and an embodiment of the invention is not limited thereto.

The bezel region BZA may be adjacent to the transmission region TA. A shape of the transmission region TA may be defined substantially by the bezel region BZA. In an embodiment, for example, the bezel region BZA may be disposed outside the transmission region TA, and may surround the transmission region TA. However, this is illustrated as an example, and in an alternative embodiment, the bezel region BZA may be adjacent to one side of the transmission region TA or may be omitted. In addition, the bezel region BZA may be disposed not on the front surface but on the side surface of the electronic apparatus ED.

The bezel region BZA may be a region having a lower light transmittance than the transmission region TA. The bezel region BZA may correspond to a region in which a material having a predetermined color is printed. The bezel region BZA may block a light transmission, and thus may effectively prevent a component of the display module DM, which is disposed to overlap the bezel region BZA, from being visible to the outside.

The display panel DP may be disposed between the window WM and the housing HAU. The display panel DP may display an image in response to an electrical signal. The display panel DP according to an embodiment may be an emissive display panel, but is not specially limited thereto. In an embodiment, for example, the display panel DP may be an organic light-emitting display panel, an inorganic light-emitting display panel, or a quantum dot light-emitting display panel. A light-emitting layer of the organic light-emitting display panel may include an organic light-emitting material, and a light-emitting layer of the inorganic light-emitting display panel may include an inorganic light-emitting material. A light-emitting layer of the quantum dot light-emitting display panel may include quantum dots, quantum rods, etc. Hereinafter, for convenience of description, embodiments where the display panel DP is an organic light-emitting display panel will be described in detail.

The display panel DP may include a display region DA and a non-display region NDA. The display region DA may be a region in which a light-emitting element is disposed. The light-emitting element may generate light in response to an electrical signal, and may output an image through the display region DA. In an embodiment, for example, the light-emitting element may be a light-emitting diode, but an embodiment of the invention is not necessarily limited thereto. The display region DA may overlap at least a part of the transmission region TA.

The display panel DP may include a sensing region DP-SA, and may correspond to the sensing region SA (see FIG. 1) of the electronic apparatus ED described above. That is, in the display region DA, the sensing region DP-SA may be a region having a relatively high light transmittance. The sensing region DP-SA may be defined inside the display region DA. However, an embodiment of the invention is not limited thereto, and a part of the sensing region DP-SA may be defined inside the non-display region NDA.

The light-emitting element may be disposed in the sensing region SA. The density of the light-emitting element disposed in the sensing region SA may be less than the density of the light-emitting element disposed in another region spaced apart from the sensing region SA in the display region DA. That is, the sensing region SA may be a region having lower resolution than other regions of the display region DA.

The non-display region NDA may be adjacent to the display region DA. In an embodiment, for example, the non-display region NDA may surround the display region DA. However, an embodiment of the invention is not limited thereto, and the non-display region NDA may be defined as various shapes. The non-display region NDA may be a region in which a driving circuit for driving the light-emitting element disposed in the display region DA, and signal lines and pads for providing an electrical signal to the light-emitting element are disposed. The non-display region NDA may overlap at least a part of the bezel region BZA, and the bezel region BZA may effectively prevent components, disposed in the non-display region NDA, from being viewed to the outside.

The electronic apparatus ED may include a flexible printed circuit board FCB which is electrically connected to the display panel DP. The flexible printed circuit board FCB may be disposed on the non-display region NDA of the display panel DP and coupled to the display panel DP. The flexible printed circuit board FCB may be connected to a main circuit board. The main circuit board may be an electronic component to constitute the electronic module EM.

A partial region of the display panel DP may be provided as a bending region BA. In an embodiment, the bending region BA may be included in the non-display region NDA. The bending region BA may be bent about a bending axis in parallel to the first direction DR1. The flexible printed circuit board FCB may overlap a part of the display panel DP on a plane, due to the bending of the bending region BA. The display panel may further include a data driver DDV. The data driver DDV may include a data driving circuit for driving pixels inside the display region DA. In an embodiment, the data driver DDV may be provided in a form of an integrated circuit chip installed inside the non-display region NDA of the display panel DP. However, an embodiment of the invention is not limited thereto, and the data driver DDV may be installed on the flexible printed circuit board FCB.

The window WM and the housing HAU may be coupled to each other and constitute the exterior of the electronic apparatus ED. The display module DM, the electronic module EM, and the power supply module PSM may be accommodated in an inner space formed by coupling the window WM and the housing HAU.

The housing HAU may include a material having a relatively high stiffness. In an embodiment, for example, the housing HAU may include a plurality of frames and/or plates containing glass, plastic, or metal, or composed of a combination thereof. The housing HAU may absorb an impact applied from the outside, or prevent foreign matters/moisture, or the like from being introduced from the outside, thereby protecting components of the electronic apparatus ED which are accommodated in the housing HAU.

Referring to FIG. 3, an embodiment of the display device DD may include the display panel DP and a sensor SS. The sensor SS may include at least any one of an input sensor, an antenna sensor, or a fingerprint sensor.

The electronic module EM may include a control module E-10, a wireless communication module E-20, an image input module E-30, an audio input module E-40, an audio output module E-50, a memory E-60, an external interface module E-70, etc. The electronic module EM may include a main circuit board, and modules included in the electronic module EM may be mounted on the main circuit board, or electrically connected to the main circuit board through a flexible circuit board. The electronic module EM may be electrically connected to the power supply module PSM.

The control module E-10 may control an overall operation of the electronic apparatus ED. In an embodiment, for example, the control module E-10 may activate or inactivate the display device DD in response to a user's input. The control module E-10 may control the image input module E-30, the audio input module E-40, the audio output module E-50, or the like, in response to the user's input. The control module E-10 may include at least one microprocessor.

The wireless communication module E-20 may transmit/receive a wireless signal to/from another terminal using a Bluetooth or a Wi-Fi line. The wireless communication module E-20 may transmit/receive an audio signal using a common communication line. The wireless communication module E-20 may include a plurality of antenna modules.

The image input module E-30 may process an image signal and convert the image signal into image data displayable on the display device DD. The audio input module E-40 may receive an external audio signal which is input by a microphone in a recording mode, a voice recognition mode, or the like, and may convert the external audio signal into electrical audio data. The audio output module E-50 may convert and output audio data which is received from the wireless communication module E-20 or which is stored in the memory E-60.

The external interface module E-70 may serve as an interface connected to an external charger, a wired/wireless data port, a card socket (for example, a memory card, a SIM/UIM card), etc.

The power supply module PSM may supply power required for an overall operation of the electronic apparatus ED. In an embodiment, for example, the power supply module PSM may include a typical battery device.

Referring to FIGS. 2 and 3, the electro-optical module EOM may overlap the sensing region DP-SA and may be disposed under the display panel DP. The electro-optical module EOM may be an electronic component which, through the sensing region DP-SA, receives a light signal provided from the outside, or outputs a light signal to the outside. In an embodiment, for example, the electro-optical module EOM may include a camera module and/or a proximity sensor. The camera module may capture an external image through the sensing region DP-SA. The proximity sensor may be a sensor that uses information received through the sensing region DP-SA to measure the distance between an object and the electronic apparatus ED. However, an embodiment of the electro-optical module EOM is not limited thereto, and the electro-optical module EOM may further include a sensor for recognizing a part of a user's body (for example, a fingerprint, an iris, or a face), or a small-sized lamp for emitting light.

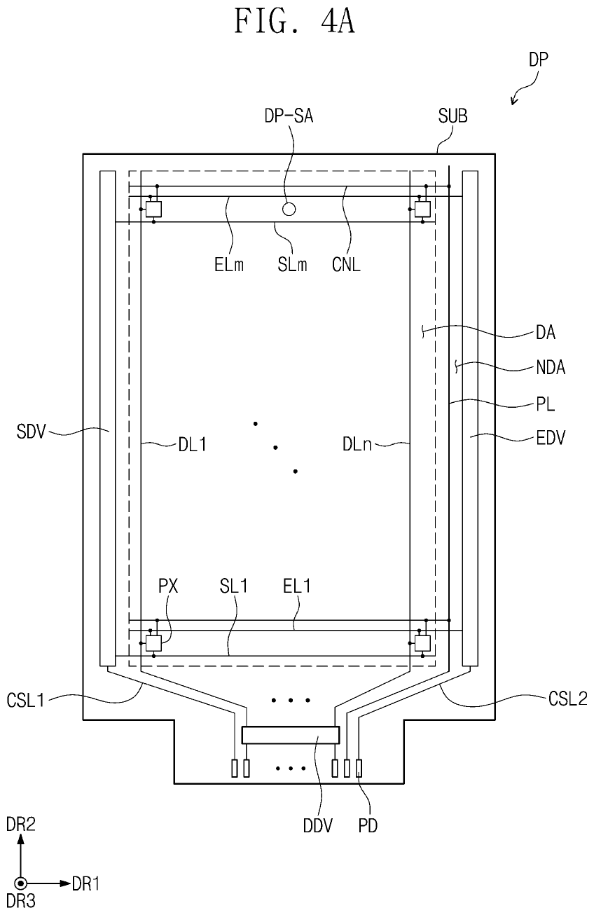

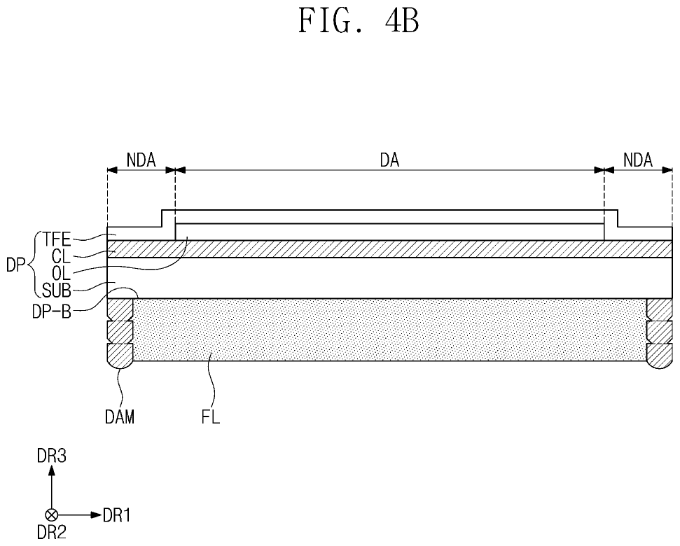

Referring back to FIG. 2, the electronic apparatus ED may include a dam DAM disposed on the rear surface of the display panel DP. Although not illustrated herein, the electronic apparatus ED may include a functional layer FL (see FIG. 4B) disposed on the rear surface of the display panel DP. The functional layer FL may be formed directly on a rear surface DP-B (see FIG. 4B) of the display panel DP. That is, the functional layer FL may be coupled to a component defining the rear surface DP-B of the display panel DP without a separate adhesive layer. The functional layer FL may be a single layer or have a structure in which a plurality of layers are stacked sequentially. In addition, the functional layer FL may include a material having a shock resistance or light-shielding property. That is, the functional layer FL has the shock resistance, and may thus protect the display panel DP from an external impact or interference delivered to the rear surface of the display panel DP. The functional layer FL has a light-shielding function, and may thus effectively prevent the emission of light to the rear surface of the display panel DP. The functional layer FL may prevent electronic components disposed under the display panel DP from being visible or see-through from the outside due to the emission of light to the rear surface DP-B of the display panel DP.

FIG. 4A is a plan view of a display panel DP according to an embodiment of the invention. FIG. 4B is a cross-sectional view of a part of an electronic apparatus according to an embodiment of the invention.

Referring to FIG. 4A, in an embodiment, the display panel DP may include a base substrate SUB, pixels PX, signal lines SL1 to SLm, DL1 to DLn, EL1 to ELm, CSL1, CSL2, PL, and CNL electrically connected to the pixels PX, a scan driver SDV, a data driver DDV, and a light emission driver EDV.

The base substrate SUB may provide a base surface on which elements and wires of the display panel DP are disposed on a plane parallel with each of a first direction DR1 and a second direction DR2. The base substrate SUB may include a display region DA and a non-display region NDA respectively corresponding to the display region DA and the non-display region NDA of the aforementioned display panel DP.

The display region DA may have the pixels PX disposed therein and thus display an image. The non-display region NDA may be adjacent to the display region DA, and may thus be a region in which an image is not displayed. The scan driver SDV, the data driver DDV, the light emission driver EDV, and the like for driving the pixels PX may be disposed in the non-display region NDA. However, at least one selected from the scan driver SDV, the data driver DDV, and the light emission driver EDV may be disposed in the display region DA to decrease an area (or to reduce a size) of the non-display region NDA.

The pixels PX may each include a light-emitting element, and a pixel driving circuit composed of transistors (for example a switching transistor, a driving transistor, etc.) connected to the light-emitting element and at least one capacitor. The pixels PX may each emit light in response to an electrical signal applied to the pixels PX and display an image within the display region DA. Some of the pixels PX may include a transistor disposed in the non-display region NDA, but an embodiment of the invention is not limited thereto.

The signal lines SL1 to SLm, DL1 to DLn, EL1 to ELm, CSL1, CSL2, PL, and CNL may include scan lines SL1 to SLm, data lines DL1 to DLn, light emission lines EL1 to ELm, first and second control lines CSL1 and CSL2, a power supply line PL, and connection lines CNL. Here, m and n represent a natural number of 2 or more.

The data lines DL1 to DLn may cross the scan lines SL1 to SLm and the light emission lines EL1 to ELm while being insulated therefrom. In an embodiment, for example, the scan lines SL1 to SLm may extend in the first direction DR1 to be connected to the scan driver SDV. The data lines DL1 to DLn may extend in the second direction DR2 to be connected to the data driver DDV. The light emission lines EL1 to ELm may extend in the first direction DR1 to be connected to the light emission driver EDV.

The power supply line PL may extend in the second direction DR2 and be disposed in the non-display region NDA. In an embodiment, the power supply line PL may be disposed between the display region DA and the light emission driver EDV. However, a position where the power supply line PL is disposed is not limited thereto.

The connection lines CNL may extend in the first direction DR1, and may be arranged along the second direction DR2 to be connected to the power supply line PL and the pixels PX. Each of the connection lines CNL may be disposed on a layer differing from a layer on which the power supply line PL is disposed, and may thus be electrically connected to the power supply line PL through a contact hole. However, an embodiment of the invention is not limited thereto, and the connection lines CNL may be integrally formed with the power supply line PL as a single unitary and indivisible part in (or directly on) a same layer. A power supply voltage applied to the power supply line PL may be applied to the pixels PX through the connection lines CNL.

The first control line CSL1 may be connected to the scan driver SDV. The second control line CSL2 may be connected to the light emission driver EDV.

Pads PD may be disposed adjacent to a lower end of the non-display region NDA. The pads PD may be disposed more adjacent to a lower end of the display panel DP than the data driver DDV. The pads PD may be disposed to be spaced apart from each other along the first direction DR1. The pads PD may be respectively connected to corresponding signal lines among the signal lines. In an embodiment, for example, the power supply line PL, the first control line CSL1, and the second control line CSL2 may be electrically connected to the pads PD, and the data lines DL1 to DLn may be electrically connected to the corresponding pads PD respectively through the data driver DDV. The pads PD may be parts to which the aforementioned flexible printed circuit board FCB (see FIG. 2) is electrically connected. Accordingly, an electrical signal provided from the flexible printed circuit board FCB (see FIG. 2) may be transmitted to the display panel DP through the pads PD.

The scan driver SDV may generate scan signals in response to a scan control signal. The scan signals may be applied to the pixels PX through the scan lines SL1 to SLm. The data driver DDV may generate, in response to a data control signal, data voltages corresponding to image signals. The data voltages may be applied to the pixels PX through the data lines DL1 to DLn. The light emission driver EDV may generate light emission signals in response to a light emission control signal. The light emission signals may be applied to the pixels PX through the light emission lines EL1 to ELm.

The pixels PX may receive the data voltages in response to the scan signals. The pixels PX may emit images by generating, in response to the light emission signals, light with a luminance corresponding to the data voltages. The emission time of the pixels PX may be controlled by the light emission signals.

Referring to FIG. 4B, in an embodiment, the display panel DP may include the base substrate SUB, a circuit layer CL, a display element layer OL, and an encapsulation layer TFE. In such an embodiment, a functional layer FL and a dam DAM may be disposed on a rear surface DP-B of the display panel DP. The display panel DP may include the rear surface DP-B facing the functional layer FL. The rear surface DP-B of the display panel DP may substantially correspond to a rear surface of the base substrate SUB, and hereinafter, the same reference numeral or symbol as that of the rear surface DP-B of the display panel DP is used for the rear surface of the base substrate SUB.

The base substrate SUB may provide a base surface on which the circuit layer CL is disposed. The base substrate SUB may be a rigid substrate or a flexible substrate capable of bending, folding, rolling, or the like. The base substrate SUB may be a glass substrate, a metal substrate, a polymer substrate, or the like. However, an embodiment of the invention is not limited thereto, and the base substrate SUB may include an inorganic layer, a synthetic resin layer, or a composite material layer.

The base substrate SUB may have a multi-layered structure. In an embodiment, for example, the base substrate SUB may include synthetic resin layers and a single- or multi-layered inorganic layer disposed between the synthetic resin layers. The synthetic resin layers may each include an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, a perylene-based resin, or the like, but a material of the synthetic resin layers is not limited thereto.

The circuit layer CL may be disposed on the base substrate SUB. The circuit layer CL may include at least one insulating layer, a semiconductor pattern, and a conductive pattern. The insulating layer, the semiconductor pattern and the conductive pattern, which are included in the circuit layer CL, may form or define driving elements, signal lines, and pads in the circuit layer CL.

The display element layer OL may be disposed on the circuit layer CL. The display element layer OL may include light-emitting elements disposed in the display region DA. The light-emitting elements may include an organic light-emitting element, an inorganic light-emitting element, a micro-light emitting diode (LED), or a nano LED, but are not particularly limited. The light-emitting elements of the display element layer OL may be electrically connected to the driving elements of the circuit layer CL, and may generate light within the display region DA in response to a signal provided by the driving elements.

The encapsulation layer TFE may be disposed on the display element layer OL and may seal the light-emitting elements. The encapsulation layer TFE may include at least one thin film so as to protect the display element layer OL and improve the optical efficiency of the display element layer OL. The encapsulation layer TFE may include at least one of an inorganic film or an organic film. In an embodiment, the encapsulation layer TFE may include a stacked structure of inorganic films and an organic film disposed between the inorganic films, but an embodiment of the invention is not particularly limited thereto. The inorganic film of the encapsulation layer TFE may protect the light-emitting element from moisture/oxygen. The organic film of the encapsulation layer TFE may protect the light-emitting element from foreign matters such as dust particles.

In an embodiment, a sensor layer (not shown) may be disposed on the display panel DP. In an embodiment, the sensor layer may be formed on the display panel DP through a continuous process. In such an embodiment, the sensor layer may be directly disposed on the display panel DP without a separate adhesive layer. However, an embodiment is not necessarily limited thereto, and alternatively, the sensor layer may be coupled to the display panel DP through an adhesive layer.

The sensor layer may include at least one of an input sensor, an antenna sensor, or a fingerprint sensor. In an embodiment, for example, the sensor layer may include an input sensor, and the input sensor may sense an external input and provide an input signal having information about the external input so that the display panel DP may generate an image corresponding to the external input. The input sensor may be driven through various methods such as a capacitive method, a resistive film method, an infrared method, a sound wave method, or a pressure method, but an embodiment of the invention is not limited thereto. An anti-reflective layer or the like may be further disposed on the sensor layer.

The functional layer FL may be disposed on the rear surface DP-B of the display panel DP. In an embodiment, for example, the functional layer FL may be formed directly on the rear surface DP-B of the display panel DP. In such an embodiment, the functional layer FL may be coupled to the base substrate SUB without a separate adhesive layer. The functional layer FL may be provided as or defined by a single layer instead of a plurality of functional layers stacked in the third direction DR3. The functional layer FL may include a light-shielding material and a shock-absorbing material. In an embodiment, for example, the light-shielding material may include a black pigment or a black dye as a carbon-based heat-dissipating material, thereby exhibiting a light-shielding function. In an embodiment, for example, the shock-absorbing material may include an acrylate-based polymer resin or a urethane-based polymer resin. The functional layer FL may absorb a shock applied from the outside, resulting in protecting the display panel DP from an external impact.

The dam DAM may be disposed on the rear surface DP-B of the display panel DP. The dam DAM may be formed directly on the rear surface DP-B of the display panel DP. According to an embodiment of the invention, the dam DAM may be formed to be in direct contact with opposing side surfaces of the functional layer FL which are opposite to each other in the first direction DR1. The dam DAM may be formed overlapping an edge of the display panel DP so that the functional layer FL may not overflow to the outside of the display panel DP. The dam DAM may include a light-shielding material. In an embodiment, for example, the dam DAM may include a black pigment or a black dye as a carbon-based material.

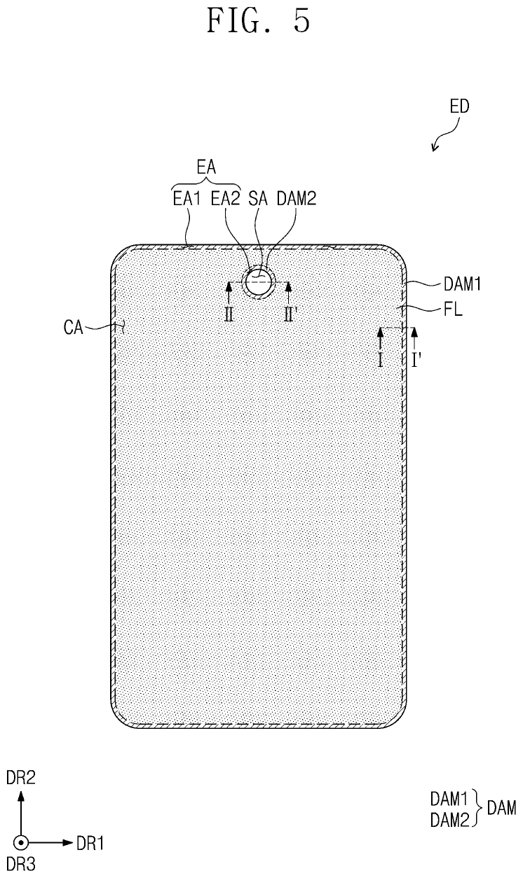

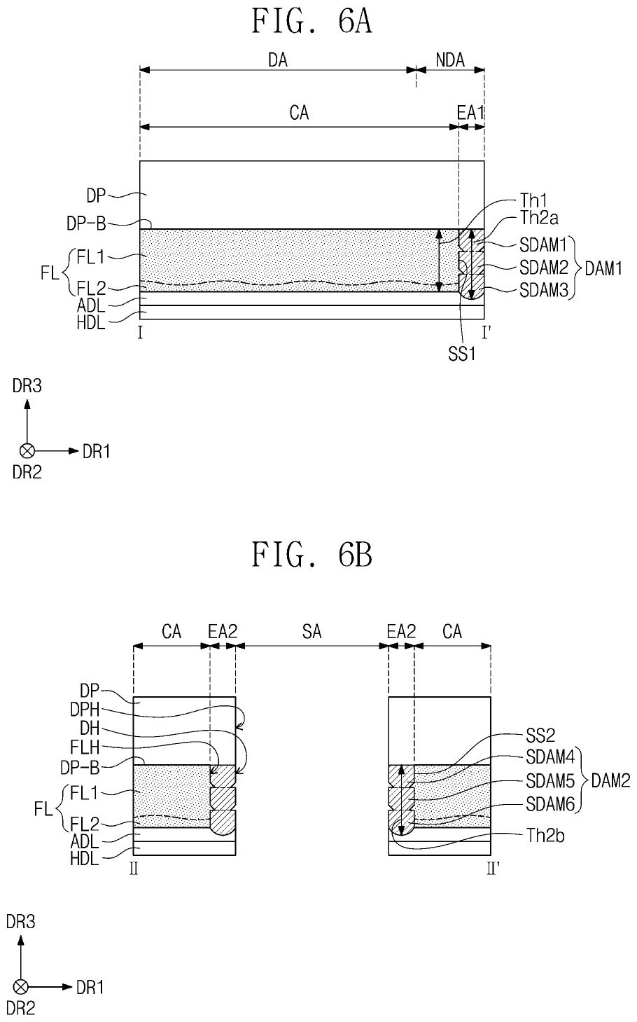

FIG. 5 is a plan view of an electronic apparatus according to an embodiment of the invention. Specifically, the plan view illustrates a functional layer FL and a dam DAM which are disposed on the rear surface DP-B (see, FIG. 4B) of the display panel DP (see FIG. 4B). FIG. 6A is a cross-sectional view of a portion of an electronic apparatus taken along line I-I′ of FIG. 5. FIG. 6B is a cross-sectional view of a portion of an electronic apparatus taken along line II-II′ of FIG. 5.

Referring FIGS. 5 to 6B, a central region CA and an edge region EA, adjacent to the central region CA, may be defined in the display panel DP. The edge region EA may be a region defined along an edge of the display panel DP. The edge region EA may include a first edge region EA1 surrounding the central region CA and a second edge region EA2 surrounded by the central region CA. The first edge region EA1 is a region defined along the edge of the display panel DP, and the second edge region EA2 is a region defined along a sensing region SA. The central region CA may correspond to the display region DA illustrated in FIG. 2, and the first edge region EA1 may correspond to the non-display region NDA. The functional layer FL may be disposed overlapping the central region CA. However, an embodiment of the invention is not limited to what is illustrated, and the functional layer FL may be disposed overlapping a part of the first edge region EA1 or a part of the second edge region EA2.

The dam DAM may include a first dam DAM1 overlapping the first edge region EA1 and a second dam DAM2 overlapping the second edge region EA2. The first dam DAM1 may be disposed to surround the functional layer FL. The second dam DAM2 may be disposed to be surrounded by the functional layer FL. According to an embodiment of the invention, a side surface of the functional layer FL may be in direct contact with the dam DAM. In such an embodiment, a first side surface SS1 of the functional layer FL may be in contact with the first dam DAM1, and a second side surface SS2 of the functional layer FL may be in contact with the second dam DAM2.

The first dam DAM1 and the second dam DAM2 may each include a plurality of sub-dams sequentially stacked one on another. In an embodiment, for example, the first dam DAM1 may include a first sub-dam SDAM1, a second sub-dam SDAM2, and a third sub-dam SDAM3, and the second dam DAM2 may include a fourth sub-dam SDAM4, a fifth sub-dam SDAM5, and a sixth sub-dam SDAM6.

The first sub-dam SDAM1 may be disposed directly on the rear surface DP-B of the display panel DP, the second sub-dam SDAM2 may be disposed directly on the first sub-dam SDAM1, and the third sub-dam SDAM3 may be disposed directly on the second sub-dam SDAM2. The first sub-dam SDAM1, the second sub-dam SDAM2, and the third sub-dam SDAM3 may include a same material as each other. In an embodiment, for example, the first sub-dam SDAM1, the second sub-dam SDAM2, and the third sub-dam SDAM3 may each include a black pigment or a black dye as a carbon-based material. The number of the sub-dams included in the first dam DAM1 is not limited to those illustrated in FIG. 6A, and the first dam DAM1 may include four or more sub-dams.

The fourth sub-dam SDAM4 may be disposed directly on the rear surface DP-B of the display panel DP, the fifth sub-dam SDAM5 may be disposed directly on the fourth sub-dam SDAM4, and the sixth sub-dam SDAM6 may be disposed directly on the fifth sub-dam SDAM5. The fourth sub-dam SDAM4, the fifth sub-dam SDAM5, and the sixth sub-dam SDAM6 may include a same material as each other. In an embodiment, for example, the fourth sub-dam SDAM4, the fifth sub-dam SDAM5, and the sixth sub-dam SDAM6 may each include a black pigment or a black dye as a carbon-based material. The number of the sub-dams included in the second dam DAM2 is not limited to those illustrated FIG. 6B, and the second dam DAM2 may include four or more sub-dams.

Referring to FIGS. 6A and 6B, the functional layer FL may include a plurality of layers. In an embodiment, for example, the functional layer FL may include a first functional layer FL1 and a second functional layer FL2. The first functional layer FL1 may be disposed on the rear surface DP-B of the display panel DP. The second functional layer FL2 may be disposed on the first functional layer FL1. The first functional layer FL1 and the second functional layer FL2 may include a same material as each other. The first functional layer FL1 and the second functional layer FL2 may be connected and formed integrally with each other as a single unitary and indivisible part.

Referring to FIG. 6B, the display panel DP may be provided a panel hole DPH defined therethrough to correspond to the electro-optical module EOM (see FIG. 2). The electro-optical module EOM may receive an external input (for example, light) through the panel hole DPH or may provide an output to the outside. The functional layer FL may be provided with a functional hole FLH defined therethrough to correspond to the electro-optical module EOM. The functional hole FLH may be defined by the second side surface SS2 of the functional layer FL. The panel hole DPH and the functional hole FLH may overlap the sensing region SA. According to an embodiment of the invention, a size of the panel hole DPH may be less than a size of the functional hole FLH. The panel hole DPH is surrounded by the second edge region EA2, and the functional hole FLH is surrounded by the central region CA. Since the second dam DAM2 is disposed overlapping the second edge regions EA2, the panel hole DPH and a dam hole DH defined by the second dam DAM2 may be arranged in the third direction DR3, and the size of the panel hole DPH may be less than the size of the functional hole FLH.

Referring to FIGS. 6A and 6B, the second functional layer FL2 may provide a flat surface. The second functional layer FL2 may provide a flat surface facing the rear surface DP-B of the display panel DP. Accordingly, the functional layer FL may have a uniform thickness Th1 along the rear surface DP-B of the display panel DP. According to an embodiment of the invention, the thickness Th1 of the functional layer FL may be equal to or less than a thickness Th2a of the first dam DAM1 or a thickness Th2b of the second dam DAM2. In an embodiment, for example, the thickness Th1 of the functional layer FL may be in a range of about 50 micrometers (μm) to about 250 μm. In an embodiment, for example, the thickness Th1 of the functional layer FL may be in a range of about 100 μm to about 150 μm. The thickness Th2a of the first dam DAM1 and the thickness Th2b of the second dam DAM2 may be the same as each other. Each of the thickness Th2a of the first dam DAM1 and the thickness Th2b of the second dam DAM2 may be about 250 μm or greater.

Referring FIGS. 5 to 6B, the electronic apparatus ED according to an embodiment of the invention may include the functional layer FL and the dam DAM on the rear surface DP-B of the display panel DP. The functional layer FL may have a uniform thickness Th1 along the rear surface DP-B of the display panel DP since the side surfaces SS1 and SS2 of the functional layer FL are in direct contact with the dam DAM. Since the functional layer FL, including a light-shielding material up to a region adjacent to the edge region EA of the display panel DP has the uniform thickness Th1, and the dam DAM including a light-shielding material is disposed in the edge region EA, it is possible to block light emitted to the rear surface of the display panel DP throughout the display panel DP. As a result, the functional layer FL may effectively prevent electronic components disposed under the display panel DP from being visible or see-through from the outside due to the emission of light to the rear surface DP-B of the display panel DP throughout the display panel DP.

Referring FIGS. 6A and 6B, in an embodiment, a heat dissipation layer HDL may be disposed under the functional layer FL and the dams DAM1 and DAM2. In such an embodiment, the heat dissipation layer HDL may be disposed on the functional layer FL and the dams DAM1 and DAM2, which are spaced apart from the rear surface DP-B of the display panel DP in an opposite direction to the third direction DR3. The heat dissipation layer HDL may perform a heat-dissipating function to release heat, generated from members of the electronic apparatus ED (see FIG. 1) having the display panel DP, to the outside. In an embodiment, for example, the heat dissipation layer HDL may include copper (Cu). The heat dissipation layer HDL may include an electromagnetic shielding material. Since the heat dissipation layer HDL includes the electromagnetic shielding material, the heat dissipation layer HDL may prevent an electric field and a magnetic field which are generated from electronic components or the like disposed under the heat dissipation layer HDL from being transmitted to the display panel DP disposed thereabove.

In an embodiment, an adhesive layers ADL may be disposed between the heat dissipation layer HDL and the functional layer FL and between the heat dissipation layer HDL and the dams DAM1 and DAM2. The heat dissipation layer HDL may be adhered to the functional layer FL and the dams DAM1 and DAM2 by the adhesive layer ADL. The adhesive layer ADL may be a pressure sensitive adhesive film (PSA), or an adhesive resin layer.

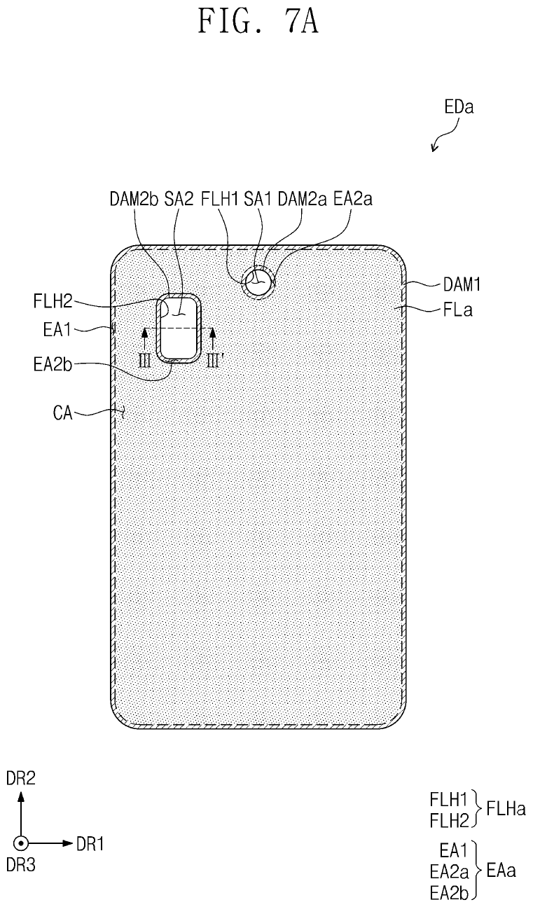

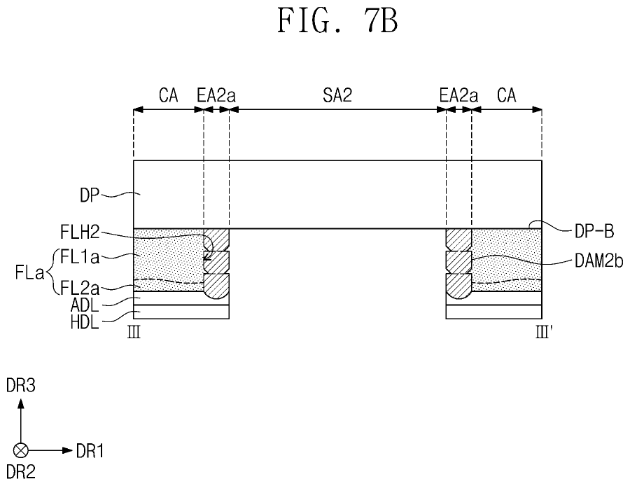

FIG. 7A is a plan view of an electronic apparatus EDa according to an embodiment of the invention. FIG. 7B is a cross-sectional view of a portion of an electronic apparatus EDa taken along line III-III′ of FIG. 7A. Any repetitive detailed description of the same or like elements as those described above will be omitted for convenience of description.

Referring to FIGS. 7A and 7B, in an embodiment of an electronic apparatus DAa, an edge region EAa may include a first edge region EA1 surrounding a central region CA and second edge regions EA2a and EA2b surrounded by the central region CA. A functional layer FLa may overlap the central region CA. A first dam DAM1 may overlap the first edge region EA1, and second dams DAM2a and DAM2b may overlap the second edge regions EA2a and EA2b.

According to an embodiment of the invention, the second edge regions EA2a and EA2b may be provided in plurality. Accordingly, the second dams DAM2a and DAM2b disposed on the second edge regions EA2a and EA2b may also be provided in plurality. In an embodiment as illustrated in FIG. 7A, the functional layer FLa may include a plurality of functional holes FLHa. The functional holes FLHa may include a first functional hole FLH1 overlapping a first sensing region SA1 and a second functional hole FLH2 overlapping a second sensing region SA2. The first functional hole FLH1 overlapping the first sensing region SA1 may be the same as the functional hole FLH overlapping the sensing region SA, illustrated in FIG. 5.

Referring to FIG. 7B, the functional layer FLa may include a first functional layer FL1a and a second functional layer FL2a. The first functional layer FL1a and the second functional layer FL2a may be connected and formed integrally with each other as a single unitary and indivisible part. The second functional hole FLH2 formed in the functional layer FLa may overlap the display panel DP. In such an embodiment, the second functional hole FLH2 may overlap the second sensing region SA2 (see FIG. 7A) of the display panel DP. An electronic component or the like may be disposed corresponding to the second functional hole FLH2 which overlaps the second sensing region SA2. In an embodiment, for example, an electronic component may include a camera module and/or a proximity sensor.

In such an embodiment, the first functional hole FLH1 may overlap the panel hole DPH as illustrated in FIG. 6B. The second functional hole FLH2 may not overlap the panel hole DPH as illustrated in FIG. 7B. The plurality of functional holes FLHa may include the first functional hole FLH1 overlapping the panel hole DPH and the second functional hole FLH2 not overlapping the panel hole DPH. That is, the second functional hole FLH2 may be formed in the functional layer FLa while overlapping a region in which no hole is defined through the display panel DP. According to an embodiment of the invention, as shown in FIG. 7A, two functional holes FLHa may be provided, but an embodiment of the invention is not limited thereto, and three or more functional holes in which an electronic component or the like is disposed may be formed on the functional layer FLa.

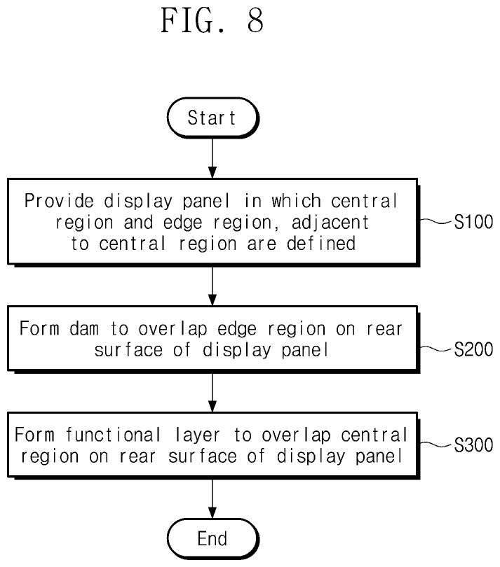

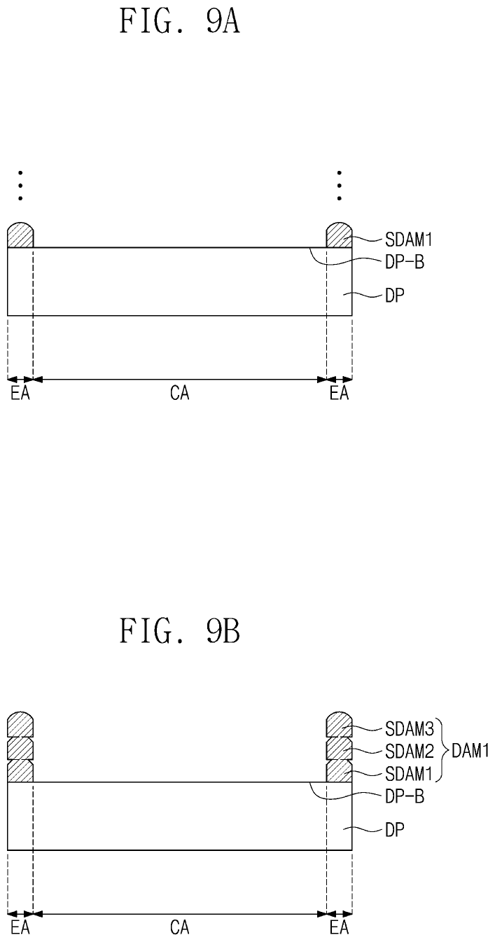

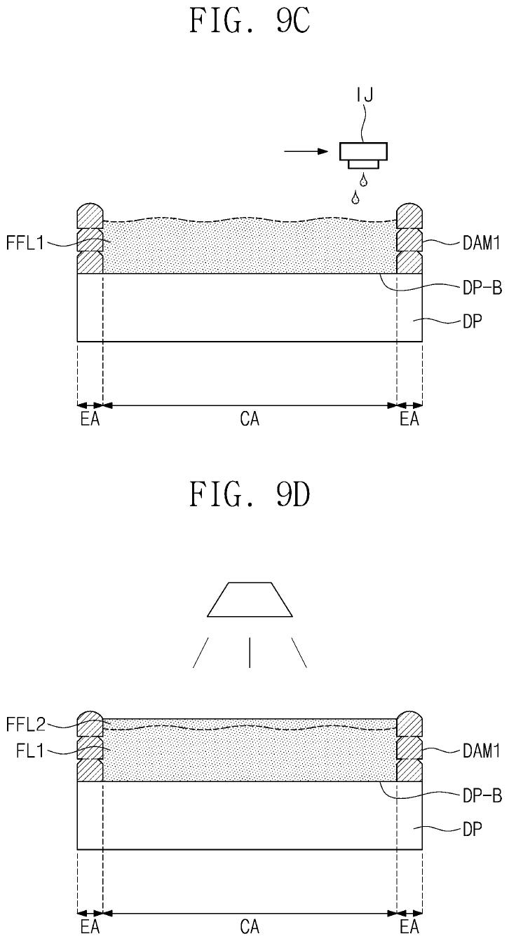

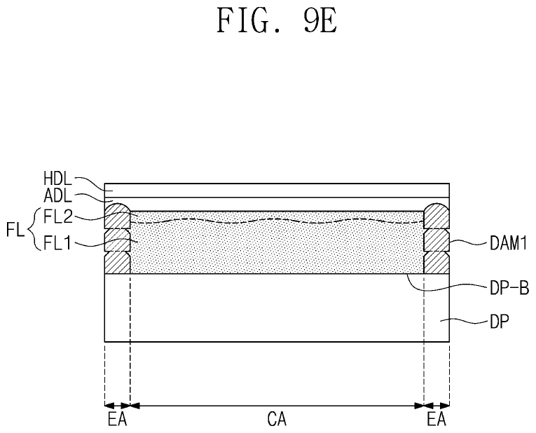

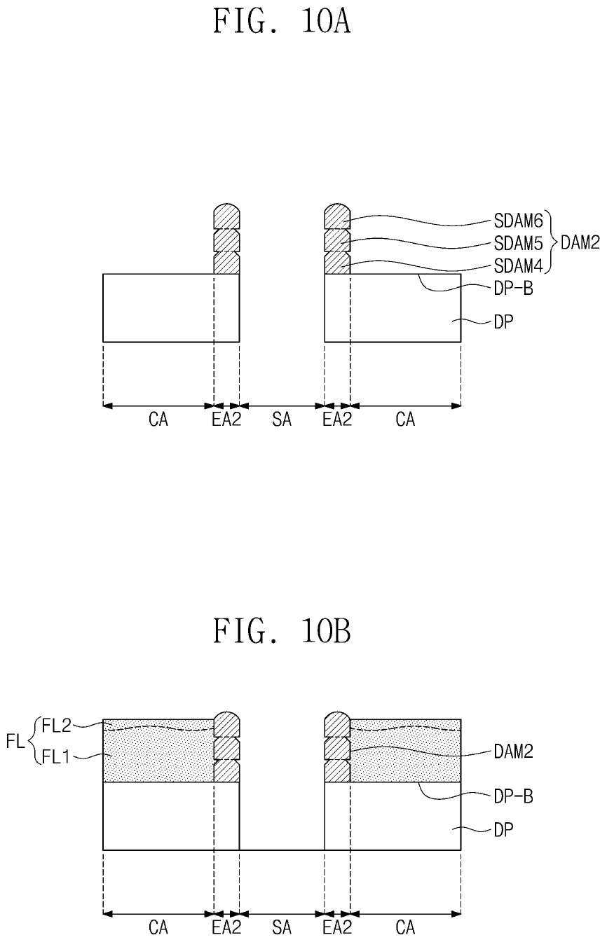

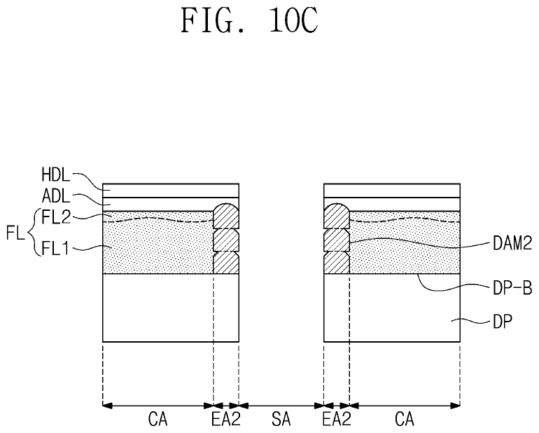

FIG. 8 is a flowchart of a method for manufacturing a display device according to an embodiment of the invention. FIGS. 9A to 9E are cross-sectional views of some operations of a method for manufacturing an electronic apparatus according to an embodiment of the invention. FIGS. 10A to 10C are cross-sectional views of some operations of a method for manufacturing an electronic apparatus according to an embodiment of the invention. Hereinafter, an embodiment of a method for manufacturing an electronic apparatus ED (see FIG. 1) according to the invention will be described with reference to FIGS. 8 to 10C.

Referring to FIGS. 8 to 9E, an embodiment of a method for manufacturing an electronic apparatus ED according to the invention may include providing a display panel DP in which a central region CA and an edge region EA, adjacent to the central region CA are defined (S100), forming a first dam DAM1 to overlap the edge region EA on a rear surface DP-B of the display panel DP (S200), and forming a functional layer FL to overlap the central region CA on the rear surface DP-B of the display panel DP (S300).

Referring to FIGS. 9A and 9B, the providing of the display panel DP in which the central region CA and the edge region EA, adjacent to the central region CA are defined (S100) and the forming of the first dam DAM1 to overlap the edge region EA on the rear surface DP-B of the display panel DP (S200) may be performed. The edge region EA may be a region defined along an edge of the display panel DP. The central region CA may be a region surrounded by the edge region EA.

The first dam DAM1 may be formed on the rear surface DP-B of the display panel DP to overlap the edge region EA. The first dam DAM1 may be formed by a plurality of sub-dams SDAM1, SDAM2, and SDAM3 which are sequentially stacked one on another. Although not illustrated, the forming of the first sub-dam SDAM1 on the rear surface DP-B of the display panel DP, the forming of the second sub-dam SDAM2 on the first sub-dam SDAM1, and the forming of the third sub-dam SDAM3 on the second sub-dam SDAM2 may be performed. A method for manufacturing an electronic apparatus according to an embodiment of the invention is not limited thereto, and may include forming four or more sub-dams.

Each of the first sub-dam SDAM1, the second sub-dam SDAM2, and the third sub-dam SDAM3 may be formed by a process of applying and photo-curing a preliminary sub-dam. In an embodiment, the first sub-dam SDAM1 may be formed by applying a first preliminary sub-dam and then photo-curing the first preliminary sub-dam through UV irradiation. The second sub-dam SDAM2 and the third sub-dam SDAM3 may be formed in the same manner as the forming of the first sub-dam SDAM1, and then the first dam DAM1 may be provided on the rear surface DP-B of the display panel DP. A method of applying the first preliminary sub-dam may include a dispensing method. However, an embodiment of the invention is not limited thereto, and the method of applying the first preliminary sub-dam may include an inkjet method, a slit method, a transfer method, or the like.

The first dam DAM1, including the first sub-dam SDAM1, the second sub-dam SDAM2 and the third sub-dam SDAM3, may include a light-shielding material. In an embodiment, for example, the first dam DAM1 may include a black pigment or a black dye as a carbon-based material.

Referring to FIGS. 9C and 9D, the forming of the functional layer FL to overlap the central region CA on the rear surface DP-B of the display panel DP (S300) may be performed.

Referring to FIG. 9C, a first preliminary functional layer FFL1 may be formed on the rear surface DP-B of the display panel DP using an application device IJ. That is, the application device IJ may be used to form the first preliminary functional layer FFL1 through an inkjet method or a dispensing method. One side surface of the first preliminary functional layer FFL1 may be in contact with a side surface of the first dam DAM1. The first preliminary functional layer FFL1 may include a light-shielding material and a shock-absorbing material. In an embodiment, for example, the light-shielding material may include a black pigment or a black dye as a carbon-based heat-dissipating material, thereby exhibiting a light-shielding function. In an embodiment, for example, the shock-absorbing material may include an acrylate-based polymer resin or a urethane-based polymer resin.

Although not illustrated, first photo-curing may be performed after the forming of the first preliminary functional layer FFL1. The first photo-curing may be performed by irradiating the first preliminary functional layer FFL1 with UV light to form a first functional layer FL1.

Referring to FIG. 9D, the forming of the functional layer FL (see FIG. 9E) by forming the second functional layer FL2 (see FIG. 9E) on the first functional layer FL1 may be performed. Although not illustrated, the forming of the second functional layer FL2 may be performed in the same manner as the forming of the first functional layer FL1. In such an embodiment, a second preliminary functional layer FFL2 may be formed on the first functional layer FL1 using the application device IJ (see FIG. 9C). The application device IJ may be used to form the second preliminary functional layer FFL2 through an inkjet method. Hereinafter, as illustrated in FIG. 9D, second photo-curing may be performed on the second preliminary functional layer FFL2. The second photo-curing may be performed by irradiating the second preliminary functional layer FFL2 with ultraviolet (UV) light to form the second functional layer FL2.

The second functional layer FL2 may provide a flat surface. The second functional layer FL2 may provide a flat surface facing the rear surface DP-B of the display panel DP. Since the second functional layer FL2 includes the flat surface, the functional layer FL may have a uniform thickness along the rear surface DP-B of the display panel DP.

Since the functional layer FL, including a light-shielding material up to a region adjacent to the edge region EA of the display panel DP has a uniform thickness, and the first dam DAM1 including a light-shielding material is disposed in the edge region EA, it is possible to block light emitted to the rear surface of the display panel DP throughout the display panel DP. As a result, the functional layer FL and the first dam DAM1 may effectively prevent electronic components disposed under the display panel DP from being viewed or see-through from the outside due to the emission of light to the rear surface DP-B of the display panel DP throughout the display panel DP.

Referring to FIG. 9E, an embodiment of a method for manufacturing an electronic apparatus according to the invention may further include disposing an adhesive layer ADL on the functional FL and the first dam DAM1, and disposing a heat dissipation layer HDL on the adhesive layer ADL. The adhesive layer ADL may be a pressure sensitive adhesive film (PSA), or an adhesive resin layer. The heat dissipation layer HDL may include copper (Cu). The heat dissipation layer HDL may include an electromagnetic shielding material. Since the heat dissipation layer HDL includes the electromagnetic shielding material, the heat dissipation layer HDL may prevent an electric field and a magnetic field which are generated from electronic components disposed under the heat dissipation layer HDL from being transmitted to the display panel DP disposed thereabove.

FIGS. 10A to 10C are cross-sectional views illustrating the forming of a second dam DAM2 and the functional layer FL in a region adjacent to the sensing region SA illustrated in FIGS. 5 and 6B.

Referring to FIGS. 5 and 10A, the providing of the display panel DP in which the central region CA and the second edge region EA2, adjacent to the central region CA are defined, and the forming of the second dam DAM2 overlapping the second edge region EA2 on the rear surface DP-B of the display panel DP may be performed. The second edge region EA2 is a region defined along an edge of the sensing region SA.

The forming of the second dam DAM2 may be the same as the forming of the first dam DAM1 illustrated in FIGS. 9A and 9B. That is, the second dam DAM2 may be formed by sequentially stacking a plurality of sub-dams SDAM4, SDAM5, and SDAM6 one on another. The second dam DAM2 including the plurality of sub-dams SDAM4, SDAM5, and SDAM6 may include a light-shielding material. In an embodiment, for example, the second dam DAM2 may include a black pigment or a black dye as a carbon-based material.

Referring to FIGS. 5 and 10B, the forming of the functional layer FL to overlap the central region CA on the rear surface DP-B of the display panel DP may be performed. The functional layer FL may include a first functional layer FL1 and a second functional layer FL2. The forming of the functional layer FL may be the same as the forming of the functional layer FL illustrated in FIGS. 9C and 9D.

The second functional layer FL2 may provide a flat surface. The second functional layer FL2 may provide a flat surface facing the rear surface DP-B of the display panel DP. Accordingly, the functional layer FL may have a uniform thickness along the rear surface DP-B of the display panel DP.

The functional layer FL, including a light-shielding material up to a region adjacent to the second edge region EA2 of the display panel DP may have a uniform thickness, and the second dam DAM2 including a light-shielding material may be disposed in the second edge region EA2. Accordingly, it is possible to block light emitted to the rear surface of the display panel DP in the second edge region EA2 and the central region CA, adjacent to the second edge region EA2.

Referring to FIG. 10C, an embodiment of a method for manufacturing an electronic apparatus according to the invention may further include disposing an adhesive layer ADL on the functional FL and the second dam DAM2, and disposing a heat dissipation layer HDL on the adhesive layer ADL. The adhesive layer ADL may be a pressure sensitive adhesive film (PSA), or an adhesive resin layer. The heat dissipation layer HDL may include copper (Cu). The heat dissipation layer HDL may include an electromagnetic shielding material. Since the heat dissipation layer HDL includes the electromagnetic shielding material, the heat dissipation layer HDL may prevent an electric field and a magnetic field which are generated from electronic components disposed under the heat dissipation layer HDL from being transmitted to the display panel DP disposed thereabove.

An electronic apparatus according to embodiments of the invention may include a functional layer on a rear surface of a display panel and may include a dam in contact with a side surface of the functional layer. Since the functional layer including a light-shielding material up to a region adjacent to an edge region of the display panel has a uniform thickness, and a dam including a light-shielding material is disposed in the edge region, it is possible to block light emitted to the rear surface of the display panel over an entire region of the display panel. As a result, the functional layer may effectively prevent electronic components disposed under the display panel from being visible or see-through from the outside due to the emission of light to the rear surface of the display panel throughout the display panel.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An electronic apparatus comprising:
a display panel in which a central region and an edge region, adjacent to the central region, are defined;
a functional layer disposed on a rear surface of the display panel and overlapping the central region; and
a dam disposed on the rear surface of the display panel and overlapping the edge region,
wherein the functional layer includes a shock-absorbing material and a light-shielding material,
the dam includes the light-shielding material, and
a side surface of the functional layer is in contact with the dam.

2. The electronic apparatus of claim 1, wherein a thickness of the functional layer is uniform along the rear surface of the display panel.

3. The electronic apparatus of claim 2, wherein the thickness of the functional layer is equal to or less than a height of the dam.

4. The electronic apparatus of claim 1, wherein
the dam comprises a plurality of sub-dams sequentially stacked one on another, and
the plurality of sub-dams includes a same material as each other.

5. The electronic apparatus of claim 1, wherein the functional layer comprises:
a first functional layer disposed on the rear surface of the display panel; and
a second functional layer disposed on the first functional layer.

6. The electronic apparatus of claim 5, wherein the first functional layer and the second functional layer includes a same material as each other.

7. The electronic apparatus of claim 1, wherein the edge region comprises
a first edge region surrounding the central region, and
a second edge region surrounded by the central region, and
the dam comprises
a first dam overlapping the first edge region, and
a second dam overlapping the second edge region.

8. The electronic apparatus of claim 7, wherein the side surface of the functional layer comprises:
a first side surface in contact with the first dam; and
a second side surface in contact with the second dam.

9. The electronic apparatus of claim 8, wherein the functional layer is provided with a functional hole overlapping the second edge region, wherein the functional hole is defined by the second side surface.

10. The electronic apparatus of claim 9, wherein the functional hole is provided in plurality, and
the display panel is provided with a panel hole defined therein to overlap at least one selected from the plurality of functional holes.

11. The electronic apparatus of claim 10, wherein a size of the panel hole is less than a size of the functional hole overlapping the panel hole.

12. The electronic apparatus of claim 10, further comprising:
an electro-optical module overlapping the functional hole.

13. The electronic apparatus of claim 1, further comprising:
a heat dissipation layer spaced apart from the rear surface of the display panel and disposed under the functional layer and the dam.

14. The electronic apparatus of claim 13, wherein the heat dissipation layer comprises a heat-dissipating material and an electromagnetic shielding material.

15. A method for manufacturing an electronic apparatus, the method comprising:
providing a display panel in which a central region and an edge region, adjacent to the central region, are defined;
forming, on a rear surface of the display panel, a dam to overlap the edge region; and
forming, on the rear surface of the display panel, a functional layer to overlap the central region,
wherein the dam is in contact with a side surface of the functional layer.

16. The method of claim 15, wherein the dam includes a plurality of sub-dams sequentially stacked one on another, and
the forming the dam comprises:
forming a first sub-dam among the plurality of sub-dams on the rear surface of the display panel; and
forming a second sub-dam among the plurality of sub-dams on the first sub-dam.

17. The method of claim 15, wherein the providing the functional layer comprises:
applying a first preliminary functional layer on the rear surface of the display panel to overlap the central region;
performing first curing on the first preliminary functional layer to provide a first functional layer;
applying a second preliminary functional layer on the first functional layer; and
performing second curing on the second preliminary functional layer to provide a second functional layer.

18. The method of claim 15, wherein the edge region comprises
a first edge region surrounding the central region, and
a second edge region surrounded by the central region, and
the forming the dam comprises
forming a first dam to overlap the first edge region, and
forming a second dam to overlap the second edge region.

19. The method of claim 18, wherein
the display panel is provided with a panel hole defined therein to overlap an electronic module, and
the second dam surrounds the panel hole.

20. The method of claim 15, further comprising:
forming an adhesive layer on the functional layer and the dam; and
forming a heat dissipation layer on the adhesive layer.
